(19) United States
(12) Patent Application Publication
(10) Pub. No.: US 2015/0342054 A1
(43) Pub. Date: Nov. 26, 2015

(54) EMBEDDED CORELESS SUBSTRATE AND METHOD FOR MANUFACTURING THE SAME

(71) Applicant: SAMSUNG ELECTRO-MECHANICS CO., LTD., Gyeonggi-Do (KR)

(72) Inventors: Yong Ho BAEK, Seoul (KR); Hyo Seung NAM, Hwasung-si (KR); Jae Ean LEE, Busan (KR); Ju Yeon BONG, Suwon-si (KR); Jung Hyun CHO, Suwon-si (KR); Kyung Hwan KO, Sejong-si (KR)

(73) Assignee: SAMSUNG ELECTRO-MECHANICS CO., LTD., Gyeonggi-Do (KR)

(21) Appl. No.: 14/667,001

(22) Filed: Mar. 24, 2015

(30) Foreign Application Priority Data
May 26, 2014 (KR) 10-2014-0063187

(51) Int. Cl. H05K 1/18; H05K 3/10; H05K 3/32; H05K 3/46; H05K 1/02; H05K 1/11

(52) U.S. Cl. CPC H05K 1/185; H05K 1/0298; H05K 1/111; H05K 1/115; H05K 3/32; H05K 3/4644; H05K 3/10; H05K 2201/10015

(57) ABSTRACT

Embodiments of the invention provide an embedded coreless substrate, and a method for manufacturing the same. According to an embodiment of the present invention, an embedded coreless substrate includes an insulating layer, a conductive pattern including a plurality of circuit pattern layers formed in(on) the insulating layer and a plurality of vias for vertically connecting the circuit pattern layers, and at least one embedded device, which is partially embedded in the insulating layer and an outer circuit pattern layer among the plurality of circuit pattern layers and of which an electrode in an embedded portion is partially or entirely covered with the outer circuit pattern layer to fix the embedded portion, is provided. Further, a method for manufacturing an embedded coreless substrate is provided.

### CROSS REFERENCE TO RELATED APPLICATION

This application claims the benefit of and priority under 35 U.S.C. §119 to Korean Patent Application No. KR 10-2014-0063187, entitled “EMBEDDED CORELESS SUBSTRATE AND METHOD MANUFACTURING THE SAME,” filed on May 26, 2014, which is hereby incorporated by reference in its entirety into this application.

### BACKGROUND

1. Field of the Invention

Embodiments of he invention relate to an embedded coreless substrate and a method for manufacturing the same, and more particularly, to an embedded coreless substrate, in which an outer circuit pattern layer partially or entirely covers an electrode in an embedded portion of an embedded device, and a method for manufacturing the same.

2. Description of the Related Art

There is a need for a PCB substrate having a high signal transmission speed with the acceleration of miniaturization of a package substrate. Further, a coreless substrate is emerging as a next generation platform of a flip chip bonding type substrate according to strong market and customer demands. The coreless substrate can be manufactured thinner than an existing core type FCB substrate. Further, an I/O count is increased, and while a PTH of a core of the existing FCB substrate acts as a noise of signal transmission in a high frequency band, the coreless substrate reduces a path of signal transmission to improve electrical performance three times that of the existing FCB substrate. Further, since the coreless substrate can implement a fine circuit on all layers, the number of layers and the body size thereof can be reduced than the existing FCB, thus lowering the price. On the other hand, since it is impossible to mount an active device and a passive device using an existing core layer in spite of these advantages, a new solution is needed.

A conventional method for manufacturing an embedded substrate forms a cavity in a CCL and fixes a die using an insulating material. In the conventional method, when there is a large number of embedded components, laser processing costs are increased, an alignment problem due to the miniaturization of the device occurs, and the device cannot be tested in an intermediate step.

### SUMMARY

Accordingly, embodiments of the invention have been made to overcome the above-described problems and, therefore, embodiments of the invention provide an embedded coreless substrate and a method for manufacturing the same, which can uniformly apply a liquid resist by adjusting the application amount of the liquid resist according to the changes in the height of the surface of an object to be applied.

In accordance with at least one embodiment, there is provided an embedded coreless substrate including an insulating layer, a conductive pattern including a plurality of circuit pattern layers formed in(on) the insulating layer and a plurality of vias for vertically connecting the circuit pattern layers, and at least one embedded device which is partially embedded in the insulating layer and an outer circuit pattern layer among the plurality of circuit pattern layers and of which an electrode in an embedded portion is partially or entirely covered with the outer circuit pattern layer to fix the embedded portion.

In accordance with at least one embodiment, the outer circuit pattern layer covers all or a portion of each of a vertical side surface of the embedded portion and an embedded horizontal surface to prevent a short circuit between the electrodes on both ends of the embedded device.

In accordance with at least one embodiment, a region of the outer circuit pattern layer, which covers the electrode in the embedded portion of the embedded device, is a pad(s) of an outer layer via(s) in the insulating layer or a circuit pattern connected to the pad(s).

In accordance with at least one embodiment, a height of the electrode cover pattern region of the outer circuit pattern layer is higher than or equal to that of the remaining circuit pattern region.

In accordance with at least one embodiment, the embedded coreless substrate further includes a protective layer formed on surfaces of the insulating layer and the outer circuit pattern layer in which the embedded device is embedded.

In accordance with at least one embodiment, the protective layer includes an opening to expose at least a portion of the surface of the outer circuit pattern layer.

In accordance with at least one embodiment, the embedded device is partially exposed by the protective layer.

In accordance with at least one embodiment, the embedded device is a capacitor device.

Next, in accordance with at least one embodiment, there is provided a method for manufacturing an embedded coreless substrate, including the step of forming an embedded coreless substrate by partially embedding at least one embedded device in an insulating layer and an outer circuit pattern layer so that all or a portion of an electrode in an embedded portion is covered with the outer circuit pattern layer and by forming a conductive pattern, which includes a plurality of circuit pattern layers and a plurality of vias for vertically connecting the circuit pattern layers, in(on) the insulating layer, wherein the plurality of circuit pattern layers include the outer circuit pattern layer.

In accordance with at least one embodiment, in the step of forming the embedded coreless substrate, the outer circuit pattern layer partially or entirely covers each of a vertical side surface of the embedded portion and an embedded horizontal surface to prevent a short circuit between electrodes on both ends of the embedded device.

In accordance with at least one embodiment, in the step of forming the embedded coreless substrate, a region of the outer circuit pattern layer, which covers the electrode in the embedded portion of the embedded device, is a pad(s) of an outer layer via(s) in the insulating layer or a circuit pattern connected to the pad(s).

In accordance with at least one embodiment, in the step of forming the embedded coreless substrate, a height of the electrode cover pattern region of the outer circuit pattern layer is higher than or equal to that of the remaining circuit pattern region.

In accordance with at least one embodiment, the step of forming the embedded coreless substrate includes an embedded device preparation step of exposing a portion of the embedded device by forming a cavity in a carrier layer and mounting the embedded device in the cavity, an outer circuit pattern layer formation step of forming the outer circuit pattern layer to cover all or a portion of the electrode in a portion, intended to be embedded, of the exposed embedded device, an embedding step of embedding the portion of the embedded device in the outer circuit pattern layer and a first insulating layer by laminating the first insulating layer on the outer circuit pattern layer, and a multilayer circuit formation step of forming a first conductive pattern including the outer layer via(s) and an inner circuit pattern layer on the first insulating layer, laminating an additional insulating layer, and forming an additional conductive pattern including an additional via(s) and an additional circuit pattern layer on the additional insulating layer.

In accordance with at least one embodiment, in the embedded device preparation step, the cavity is formed in a surface of the carrier layer having a metal foil attached thereto, in the outer circuit pattern layer formation step, the outer circuit pattern layer is formed using the metal foil as a seed layer, and the step of forming the embedded coreless substrate further includes a carrier layer removal step of exposing the first insulating layer by removing the carrier layer and the metal foil, and a protective layer formation step of forming a protective layer on surfaces of the first insulating layer and the outer circuit pattern layer exposed by the removal of the metal foil, after the embedding step or the multilayer circuit formation step.

In accordance with at least one embodiment, in the protective layer formation step, the embedded device is partially exposed by the protective layer.

In accordance with at least one embodiment, the embedded device is a capacitor device.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a cross-sectional view schematically showing an embedded coreless substrate in accordance with an embodiment of the invention.

FIGS. 2A to 2E are views schematically showing each process of a method for manufacturing an embedded coreless substrate in accordance with an embodiment of the invention.

### DETAILED DESCRIPTION

Advantages and features of the invention and methods of accomplishing the same will be apparent by referring to embodiments described below in detail in connection with the accompanying drawings. However, the invention is not limited to the embodiments disclosed below and may be implemented in various different forms. The embodiments are provided only for completing the disclosure of the invention and for fully representing the scope of the invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. According to at least one embodiment, the dimensions of some of the elements in the figures may be exaggerated relative to other elements to help improve understanding of embodiments of the invention. Like reference numerals refer to like elements throughout the specification.

Hereinafter, various embodiments of the invention will be described in detail with reference to the accompanying drawings.

First, an embedded coreless substrate according to at least one embodiment of the invention will be described in detail with reference to the drawings. At this time, the reference numeral that is not mentioned in the reference drawing may be the reference numeral that represents the same element in another drawing.

FIG. 1 is a cross-sectional view schematically showing an embedded coreless substrate in accordance with an embodiment of the invention.

Referring to FIG. 1, an embedded coreless substrate according to at least one embodiment includes an insulating layer 30, a conductive pattern 40, and at least one embedded device 10. According to at least one embodiment, as illustrated in FIG. 1, the embedded coreless substrate is implemented in a form which does not include a protective layer 50. Further, referring to FIG. 1, in according with at least one embodiment, the embedded coreless substrate further includes the protective layer 50. Hereinafter, each element will be described in detail.

First, the insulating layer 30 and the conductive pattern 40 will be described with reference to FIG. 1. According to at least one embodiment, the conductive pattern 40 is formed in(on) the insulating layer 30. According to at least one embodiment, the conductive pattern 40 includes a plurality of circuit pattern layers 41, 42b, and 43b and a plurality of vias 42a and 43a, which vertically connect the circuit pattern layers 41, 42b, and 43b. In this embodiment, the plurality of circuit pattern layers 41, 42b, and 43b includes an outer circuit pattern layer 41, which covers an electrode 10a in an embedded portion of the embedded device 10. According to at least one embodiment, the insulating layer 30 is made of an insulating material typically used in a coreless substrate. The plurality of circuit pattern layers 41, 42b, and 43b consists of the two or more circuit pattern layers 41, 42b, and 43b including the outer circuit pattern layer 41. According to at least one embodiment, the circuit pattern layers 41, 42b, and 43b are vertically connected by the vias 42a and 43a.

Next, referring to FIG. 1, the at least one embedded device 10 is partially embedded in the insulating layer 30 and the outer circuit pattern layer 41. The outer circuit pattern layer 41 is a circuit pattern layer formed in an outer portion, among the circuit pattern layers 41, 42b, and 43b, to embed the embedded device 10 therein. According to at least one embodiment, the electrode 10a in the embedded portion of the embedded device 10 is partially or entirely covered with the outer circuit pattern layer 41. The embedded portion of the embedded device 10 is embedded to be covered with the outer circuit pattern layer 41 and fixed by the outer circuit pattern layer 41 and the insulating layer 30.

According to at least one embodiment, the embedded device 10 is a passive device, for example, a capacitor device, but is not limited thereto.

According to at least one embodiment, the outer circuit pattern layer 41 covers all or a portion of each of a vertical side surface of the embedded portion and an embedded horizontal surface to prevent a short circuit between the electrodes 10a on both ends of the embedded device 10. According to at least one embodiment, when the electrodes 10a are formed on both ends of the embedded device 10, the outer circuit pattern layer 41 covers all or a portion of the embedded portion of the electrodes 10a on both ends, not the entire embedded portion of the embedded device 10, to prevent the short circuit between the electrodes 10a on both ends.

Further, according to at least one embodiment, a region of the outer circuit pattern layer 41, which covers the electrode 10a in the embedded portion of the embedded device 10, is a pad(s) of an outer layer via(s) 42a in the insulating layer 30 or a circuit pattern connected to the pad(s). Thus, unlike the conventional art, the via(s) 42a are processed in an exact pad point(s) after forming the pad(s), where the via(s) 42a is mounted, in an exactly predetermined position(s) and covering the electrode 10a in the embedded portion of the embedded device 10 with the circuit pattern connected to the pad(s) or covering the electrode 10a in the embedded portion with the pad(s), without the necessity of processing the via(s) according to the position of the electrode 10a of the embedded device 10. For example, according to at least one embodiment, the pad or the circuit pattern connected to the pad(s) cover all or a portion of each of the vertical side surface of the embedded portion and the embedded horizontal surface.

According to at least one embodiment, a height of the electrode cover pattern region of the outer circuit pattern layer 41 is higher than or equal to that of the remaining circuit pattern region.

Further, referring to FIG. 1, according to at least one embodiment, the embedded coreless substrate further includes the protective layer 50. According to at least one embodiment, the protective layer 50 the formed on surfaces of the insulating layer 30 and the outer circuit pattern layer 41 in which the embedded device 10 is embedded. According to at least one embodiment, the protective layer 50 is a PSR layer.

Further, although not shown, according to at least one embodiment, the protective layer 50 is further formed on the opposite side of the surface in which the embedded device 10 is embedded.

Referring to FIG. 1, according to at least one embodiment, the protective layer 50 has an opening 50a to expose at least a portion of the surface of the outer circuit pattern layer 41. Electrical connection with the outer circuit pattern layer 41 are performed through the opening 50a.

Further, referring to FIG. 1, according to at least one embodiment, the embedded device 10 is partially exposed by the protective layer 50.

Next, a method for manufacturing an embedded coreless substrate according to another embodiment of the invention will be described in detail with reference to the drawings. At this time, the embedded coreless substrate according to the above-described embodiment of the invention and FIG. 1 will be referenced. Thus, repeated descriptions may be omitted.

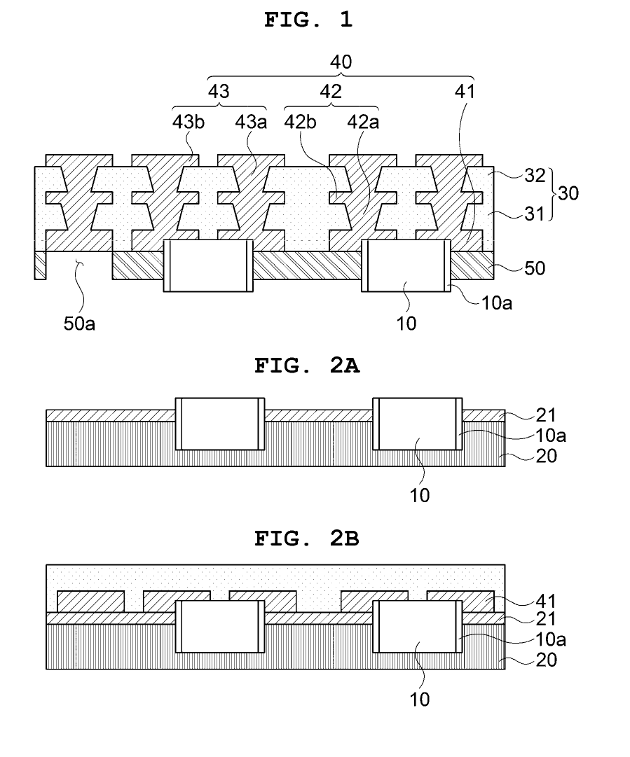

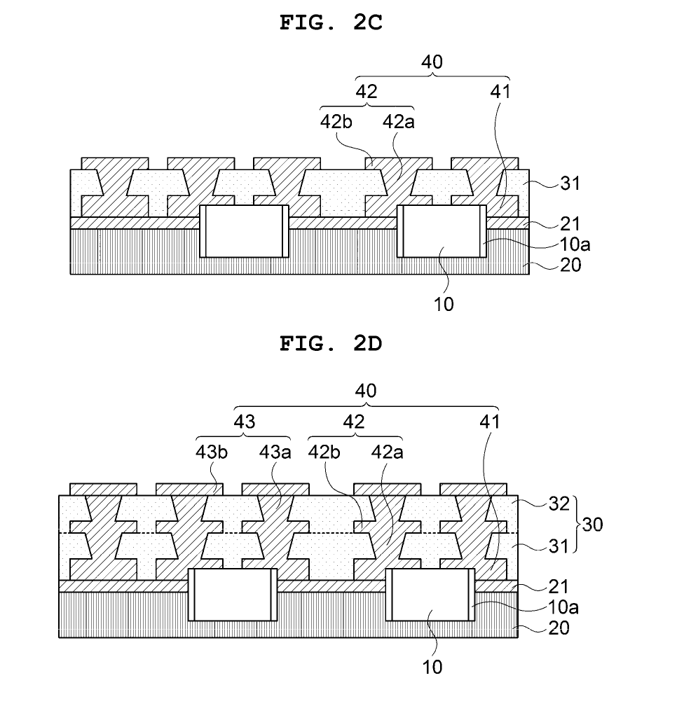

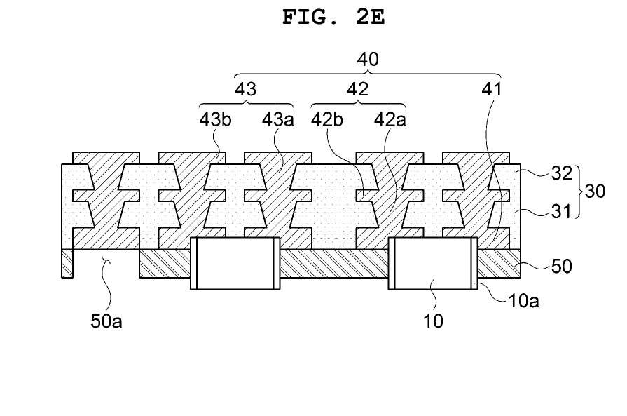

FIGS. 2A to 2E are views schematically showing each process of a method for manufacturing an embedded coreless substrate in accordance with an embodiment of the invention.

An embodiment of the method for manufacturing an embedded coreless substrate will be described. According to at least one embodiment, the method for manufacturing an embedded coreless substrate includes the step of forming an embedded coreless substrate in which at least one embedded device 10 is partially embedded in an insulating layer 30 and an outer circuit pattern layer 41. In the step of forming the embedded coreless substrate, the at least one embedded device 10 is partially embedded in the insulating layer 30 and the outer circuit pattern layer 41, so that all or a portion of an electrode 10a in an embedded portion is covered with the outer circuit pattern layer 41. Further, in the step of forming the embedded coreless substrate, a conductive pattern 40 including a plurality of circuit pattern layers 41, 42b, and 43b and a plurality of vias 42a and 43a for vertically connecting the circuit pattern layers 41, 42b, and 43b are formed in(on) the insulating layer 30. At this time, the plurality of circuit pattern layers 41, 42b, and 43b include the outer circuit pattern layer 41, which covers all or a portion of the electrode 10a in the embedded portion of the embedded device 10.

According to at least one embodiment, the step of forming the embedded coreless substrate is performed using a carrier layer 20 as shown in FIGS. 2A to 2E. Otherwise, although not shown, the embedded device 10 is partially embedded in a cavity by forming the cavity over the outer circuit pattern layer 41 and the insulating layer 30 of the coreless substrate including the insulating layer 30 and the conductive pattern 40, which includes the plurality of circuit pattern layers 41, 42b, and 43b and the plurality of vias 42a and 43a. In terms of fixation of the embedded device 10, the former, which covers the embedded electrode portion with the outer circuit pattern layer 41 using the carrier layer 20, is more advantageous than the latter.

According to at least one embodiment, the embedded device 10 is a passive device, for example, a capacitor device, but is not limited thereto.

According to at least one embodiment, in the step of forming the embedded coreless substrate, the outer circuit pattern layer 41 covers all or a portion of each of an vertical side surface of the embedded portion and an embedded horizontal surface to prevent a short circuit between the electrodes 10a on both ends of the embedded device 10.

Further, according to at least one embodiment, in the step of forming the embedded coreless substrate, a region of the outer circuit pattern layer 41, which covers the electrode 10a in the embedded portion of the embedded device 10, is a pad(s) of an outer layer via(s) 42a in the insulating layer 30 or a circuit pattern connected to the pad(s). According to at least one embodiment, the pad or the circuit pattern connected to the pad(s) covers all or a portion of each of the vertical surface of the embedded portion and the embedded horizontal surface of the embedded device 10.

According to at least one embodiment, in the step of forming the embedded coreless substrate, a height of the electrode cover pattern region of the outer circuit pattern layer 41 is higher than or equal to that of the remaining circuit pattern region.

Next, according to at least one embodiment, the step of forming the embedded coreless substrate will be described in detail with reference to FIGS. 2A to 2E. According to at least one embodiment, the step of forming the embedded coreless substrate includes an embedded device preparation step, an outer circuit pattern layer formation step, an embedding step, and a multilayer circuit formation step. Further, referring to FIGS. 2A to 2E, the step of forming the embedded coreless substrate further includes a carrier layer removal step and a protective layer formation step. Hereinafter, each step will be described in detail.

Specifically, referring to FIG. 2A, according to at least one embodiment, in the embedded device preparation step, a portion of the embedded device 10 is exposed by forming the cavity in the carrier layer 20 and mounting the embedded device 10 in the cavity. The cavity is processed in the carrier layer 20 to fit the size of the device, and the embedded device 10 is mounted in the cavity. At this time, only a portion of the embedded device 10 is embedded. Accordingly, it is possible to make substantially zero a defect rate such as misalignment or tombstone, which can be generated when mounting an embedded device in a cavity of a conventional core substrate. According to at least one embodiment, referring to FIG. 2A, the carrier layer 20 having a metal foil 21 attached thereto is prepared, and the cavity is formed in the surface to which the metal foil 21 is attached. The embedded device 10 is fixed after the embedded device 10 is mounted in the cavity of the carrier layer 20, and the metal foil 21 of the carrier layer 20 is used as a seed layer. According to an embodiment, the carrier layer 20, to which the metal foil 21 is not attached, shown in FIG. 2A, is used.

According to at least one embodiment, the carrier layer 20 temporarily fixes the embedded device 10 to the cavity. The height of the exposed embedded device 10 is adjusted by the adjustment of the depth of the cavity of the carrier layer 20, thus adjusting the depth of the embedded device 10 partially embedded in the outer circuit pattern layer 41 and the insulating layer 30. According to at least one embodiment, the warpage and stiffness of the substrate is adjusted according to the processing depth of the cavity, thus, the embedded height of the embedded device. For example, the carrier layer 20 uses PPG or other materials. For example, according to at least one embodiment, the metal foil 21 is a copper foil.

According to at least one embodiment, the embedded device 10 is a passive device, for example, a capacitor device, but is not limited thereto.

Next, the outer circuit pattern layer formation step and the embedding step will be described with reference to FIG. 2B. First, referring to FIG. 2B, in the outer circuit pattern layer formation step, the outer circuit pattern layer 41 is formed to cover all or a portion of the electrode 10a of a portion, intended to be embedded, of the embedded device 10 exposed in the embedded device preparation step. For example, at this time, according to another embodiment of the invention, the outer circuit pattern layer 41 is formed by partially exposing the embedded device 10 using the carrier layer 20 having the metal foil 21 attached thereto and using the metal foil 21, for example, a copper foil as a seed layer. According to at least one embodiment, the outer circuit pattern layer 41 is formed on the seed layer, for example, by electrolytic copper to be electrically connected to the embedded device 10.

Next, referring to FIG. 2B, in the embedding step, a first insulating layer 31 is laminated on the outer circuit pattern layer 41, so that the portion of the embedded device 10 is embedded in the outer circuit pattern layer 41 and the first insulating layer 31. Thus, finally, the embedded device 10 is fixed by the lamination of the first insulating layer 31.

According to at least one embodiment, the multilayer circuit formation step will be described with reference to FIGS. 2C and 2D. Referring to FIGS. 2C and 2D, in the multilayer circuit formation step, as shown in FIG. 2C, a first conductive pattern 42 including an outer layer via(s) 42a and an inner circuit pattern layer 42b is formed on the first insulating layer 31. Further, referring to FIG. 2D, in the multilayer circuit formation step, an additional insulating layer 32 is laminated so that an additional conductive pattern 43 including an additional via(s) 43a and an additional circuit pattern layer 43b is formed on the additional insulating layer 32. For example, the first insulating layer 31 and the additional insulating layer 32 are made of the same material. In another embodiment of the invention, the first insulating layer 31 is made of a different material from the additional insulating layer 32, and the same material is more advantageous in consideration of the adhesion between the insulating layers 30.

Further, another embodiment of the step of forming the embedded coreless substrate will be described with reference to FIG. 2E. For example, referring to FIG. 2E, the step of forming the embedded coreless substrate further includes the carrier layer removal step and the protective layer formation step after the multilayer circuit formation step. FIG. 2E shows that the carrier layer removal step and the protective layer formation step are performed after the multilayer circuit formation step, but the carrier layer removal step and the protective layer formation step are performed after the embedding step unlike as shown in FIG. 2. In terms of process, it is more advantageous to perform the carrier layer removal step and the protective layer formation step after the multilayer circuit formation step than perform the carrier layer removal step and the protective layer formation step after the embedding step. FIG. 2E can be applied to both an example of using the carrier layer 20 to which the metal foil 21 is not attached and an example of using the carrier layer 20 to which the metal foil 21 is attached.

Referring to FIG. 2E, first, in the carrier layer removal step, the carrier layer 20 is removed after the embedding step (not shown) or the multilayer circuit formation step (refer to FIGS. 2D and 2E) to expose the first insulating layer 31. According to at least one embodiment, when the metal foil 21 is attached to the carrier layer 20, the metal foil 21 is removed by etching and the like after the removal of the carrier layer 20. According to at least one embodiment, when the metal foil 21 is removed, the metal foil 21 is entirely removed or the metal foil 21 only in the remaining region, except the region used as the seed layer of the outer circuit pattern layer 41 is removed.

Further, referring to FIG. 2E, in the protective layer formation step according to an embodiment of the invention, a protective layer 50 is formed on surfaces of the first insulating layer 31 and the outer circuit pattern layer 41, which is exposed by the removal of the carrier layer 20. According to at least one embodiment, when the metal foil 21 is removed in the carrier layer removal step, the protective layer 50 is formed on the surfaces of the first insulating layer 31 and the outer circuit pattern layer 41, which is exposed by the removal of the metal foil 21. For example, the protective layer 50 is a PSR layer.

According to at least one embodiment, although not shown, in the protective layer formation step, the protective layer is also formed on the opposite side of the surface from which the carrier layer 20 is removed.

Referring to FIG. 2E, in an example, in the protective layer formation step, the embedded device 10 is partially exposed by the protective layer 50.

According to at least one embodiment, in the protective layer formation step, the protective layer 50 is formed to have an opening 50a which exposes at least a portion of the surface of the outer circuit pattern layer 41. According to at least one embodiment, electrical connection with the circuit pattern layer 41 is performed through the opening 50.

As described above, according to an embodiment of the invention, since the electrode 10a of the embedded device 10 is covered with the outer circuit pattern layer 41 and connected, it is not needed to process a separate via for connection with the electrode 10a of the embedded device 10 in the embedded substrate, thus preventing the occurrence of alignment errors of the embedded device 10. Further, according to an embodiment, alignment problems due to the miniaturization of the device can be improved by covering the electrode in the embedded portion of the device with the outer circuit pattern layer 41, not forming a cavity in a core in a conventional core substrate.

Further, the embedded device 10 can be fixed well by connecting and fixing the electrode 10a of the embedded portion to the outer circuit pattern layer 41, not fixing the embedded device 10 only by the insulating layer 30.

According to at least one embodiment, heat radiation characteristics of the embedded device 10 is improved by embedding and exposing a portion of the embedded device 10. Further, the characteristics of the device are tested even in an intermediate step of the manufacturing process when necessary.

Further, according to an embodiment of the invention, it is possible to reduce costs by partially embedding the embedded device in the carrier layer without forming a separate cavity in the substrate, thus overcoming the increase in the laser processing costs due to the processing of the cavity for embedding the device when there are a large number of the embedded devices, which was the problem when mounting the embedded device of the conventional core substrate. Further, in an embodiment, it is possible to reduce costs and further improve the flexibility of substrate design by exposing a portion of the embedded device.

Further, according to at least one embodiment, the embedded coreless substrate is implemented by implementing various shapes of cavities in the coreless substrate using a carrier to implement the embedded substrate, and the top, bottom, left, and right, size, and mounting method of the cavity of the carrier are adjusted to improve the warpage of the substrate. In addition, appropriate substrate stiffness is given to improve drivability and mountability.

According to an embodiment of the invention, it is possible to provide an embedded coreless substrate, in which an outer circuit pattern layer partially or entirely covers an electrode in an embedded portion of an embedded device, and a method for manufacturing the same.

According to an embodiment of the present invention, it is not needed to process a separate via for connection with an electrode of an embedded device in an embedded substrate by connecting the electrode of the embedded device after covering the electrode of the embedded device with an outer circuit pattern layer. Accordingly, an alignment error of the embedded device does not occur.

Terms used herein are provided to explain embodiments, not limiting the invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the invention may suitably comprise, consist or consist essentially of the elements disclosed and may be practiced in the absence of an element not disclosed. According to at least one embodiment, it can be recognized by those skilled in the art that certain steps can be combined into a single step.

The terms and words used in the specification and claims should not be interpreted as being limited to typical meanings or dictionary definitions, but should be interpreted as having meanings and concepts relevant to the technical scope of the invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the invention has been described in detail, it should be understood that various changes, substitutions, and alterations can be made hereupon without departing from the principle and scope of the invention. Accordingly, the scope of the invention should be determined by the following claims and their appropriate legal equivalents.

What is claimed is:

1. An embedded coreless substrate, comprising:
an insulating layer;
a conductive pattern comprising a plurality of circuit pattern layers formed in(on) the insulating layer and a plurality of vias for vertically connecting the circuit pattern layers; and
at least one embedded device, which is partially embedded in the insulating layer and an outer circuit pattern layer among the plurality of circuit pattern layers and of which an electrode in an embedded portion is partially or entirely covered with the outer circuit pattern layer to fix the embedded portion.

2. The embedded coreless substrate according to claim 1, wherein the outer circuit pattern layer covers all or a portion of each of a vertical side surface of the embedded portion and an embedded horizontal surface to prevent a short circuit between the electrodes on both ends of the embedded device.

3. The embedded coreless substrate according to claim 1, wherein a region of the outer circuit pattern layer, which covers the electrode in the embedded portion of the embedded device, is a pad(s) of an outer layer via(s) in the insulating layer or a circuit pattern connected to the pad(s).

4. The embedded coreless substrate according to claim 1, wherein a height of the electrode cover pattern region of the outer circuit pattern layer is higher than or equal to that of the remaining circuit pattern region.

5. The embedded coreless substrate according to claim 1, further comprising:
a protective layer formed on surfaces of the insulating layer and the outer circuit pattern layer in which the embedded device is embedded.

6. The embedded coreless substrate according to claim 2, further comprising:
a protective layer formed on surfaces of the insulating layer and the outer circuit pattern layer in which the embedded device is embedded.

7. The embedded coreless substrate according to claim 3, further comprising:
a protective layer formed on surfaces of the insulating layer and the outer circuit pattern layer in which the embedded device is embedded.

8. The embedded coreless substrate according to claim 4, further comprising:
a protective layer formed on surfaces of the insulating layer and the outer circuit pattern layer in which the embedded device is embedded.

9. The embedded coreless substrate according to claim 5, wherein the protective layer comprises an opening to expose at least a portion of the surface of the outer circuit pattern layer.

10. The embedded coreless substrate according to claim 5, wherein the embedded device is partially exposed by the protective layer.

11. The embedded coreless substrate according to claim 1, wherein the embedded device is a capacitor device.

12. A method for manufacturing an embedded coreless substrate, comprising:
forming an embedded coreless substrate by partially embedding at least one embedded device in an insulating layer and an outer circuit pattern layer, so that all or a portion of an electrode in an embedded portion is covered with the outer circuit pattern layer and by forming a conductive pattern, which includes a plurality of circuit pattern layers and a plurality of vias for vertically connecting the circuit pattern layers, in(on) the insulating layer, wherein the plurality of circuit pattern layers comprise the outer circuit pattern layer.

13. The method for manufacturing an embedded coreless substrate according to claim 12, wherein in forming the embedded coreless substrate, the outer circuit pattern layer covers all or a portion of each of a vertical side surface of the embedded portion and an embedded horizontal surface to prevent a short circuit between electrodes on both ends of the embedded device.

14. The method for manufacturing an embedded coreless substrate according to claim 12, wherein in forming the embedded coreless substrate, a region of the outer circuit pattern layer, which covers the electrode in the embedded portion of the embedded device, is a pad(s) of an outer layer via(s) in the insulating layer or a circuit pattern connected to the pad(s).

15. The method for manufacturing an embedded coreless substrate according to claim 12, wherein in forming the embedded coreless substrate, a height of the electrode cover pattern region of the outer circuit pattern layer is higher than or equal to that of the remaining circuit pattern region.

16. The method for manufacturing an embedded coreless substrate according to claim 12, wherein forming the embedded coreless substrate comprises:
an embedded device preparation step of exposing a portion of the embedded device by forming a cavity in a carrier layer and mounting the embedded device in the cavity;
an outer circuit pattern layer formation step of forming the outer circuit pattern layer to cover all or a portion of the electrode in a portion, intended to be embedded, of the exposed embedded device;
an embedding step of embedding the portion of the embedded device in the outer circuit pattern layer and a first insulating layer by laminating the first insulating layer on the outer circuit pattern layer; and
a multilayer circuit formation step of forming a first conductive pattern including the outer layer via(s) and an inner circuit pattern layer on the first insulating layer, laminating an additional insulating layer, and forming an additional conductive pattern including an additional via(s) and an additional circuit pattern layer on the additional insulating layer.

17. The method for manufacturing an embedded coreless substrate according to claim 14, wherein forming the embedded coreless substrate comprises:
an embedded device preparation step of exposing a portion of the embedded device by forming a cavity in a carrier layer and mounting the embedded device in the cavity;
an outer circuit pattern layer formation step of forming the outer circuit pattern layer to cover all or a portion of the electrode in a portion, intended to be embedded, of the exposed embedded device;
an embedding step of embedding the portion of the embedded device in the outer circuit pattern layer and a first insulating layer by laminating the first insulating layer on the outer circuit pattern layer; and
a multilayer circuit formation step of forming a first conductive pattern including the outer layer via(s) and an inner circuit pattern layer on the first insulating layer, laminating an additional insulating layer, and forming an additional conductive pattern including an additional via(s) and an additional circuit pattern layer on the additional insulating layer.

18. The method for manufacturing an embedded coreless substrate according to claim 16, wherein in the embedded device preparation step, the cavity is formed in a surface of the carrier layer having a metal foil attached thereto,
in the outer circuit pattern layer formation step, the outer circuit pattern layer is formed using the metal foil as a seed layer, and
forming the embedded coreless substrate further comprises, after the embedding step or the multilayer circuit formation step, a carrier layer removal step of exposing the first insulating layer by removing the carrier layer and the metal foil; and a protective layer formation step of forming a protective layer on surfaces of the first insulating layer and the outer circuit pattern layer exposed by the removal of the metal foil.

19. The method for manufacturing an embedded coreless substrate according to claim 18, wherein in the protective layer formation step, the embedded device is partially exposed by the protective layer.

20. The method for manufacturing an embedded coreless substrate according to claim 12, wherein the embedded device is a capacitor device.
